(19) United States
(12) Patent Application Publication
(10) Pub. No.: US 2016/0336965 A1
(43) Pub. Date: Nov. 17, 2016

(54) ERROR CORRECTION METHOD, SEMICONDUCTOR DEVICE, TRANSMISSION AND RECEPTION MODULE, AND TRANSMITTING APPARATUS

(71) Applicants: FUJITSU LIMITED, Kawasaki-shi (JP); Mobile Techno Corp., Yokohama-shi (JP)

(72) Inventors: Yohei KOGANEI, Kawasaki (JP); Chikara Kojima, Kanagawa (JP); Cong Li, Kanagawa (JP)

(73) Assignees: FUJITSU LIMITED, Kawasaki-shi (JP); Mobile Techno Corp., Yokohama-shi (JP)

(21) Appl. No.: 15/092,192

(22) Filed: Apr. 6, 2016

(30) Foreign Application Priority Data
May 11, 2015 (JP) 2015-096478

(51) Int. Cl. H03M 13/11; H03M 13/00

(52) U.S. Cl. CPC H03M 13/1105; H03M 13/616

(57) ABSTRACT

An error correction method of executing error correction for a coded signal using a space coupling LDPC, includes setting a column weight in a column direction of an element matrix that among element matrices of the space coupling LDPC, corresponds to one end side of a bit string of the signal, to be large as a parity check matrix for detecting errors in multiplying the signal.

### CROSS REFERENCE TO RELATED APPLICATIONS

This application is based upon and claims the benefit of priority of the prior Japanese Patent Application No. 2015-096478, filed on May 11, 2015, the entire contents of which are incorporated herein by reference.

### FIELD

The embodiments discussed herein are related to an error correction method, a semiconductor device, a transmission and reception module, and a transmitting apparatus.

### BACKGROUND

A signal decoding apparatus of a communication path and the like executes error correction using a predetermined parity check matrix that includes combinations of values of “0/1” in the matrix direction. Low-density parity check (LDPC) code is used as the parity check matrix.

According to a disclosed technique of a space coupling LDPC, higher error correction is executed by arranging plural respective element matrices for the LDPC in the matrix direction (see, e.g., Japanese Laid-Open Patent Publication Nos. 2013-81161 and 2013-175799). The space coupling LDPC is represented using a method of spatially representing the sequence of the element matrices in the matrix direction, or a method using a protograph. According to a disclosed technique, in the space coupling LDPC, plural element matrices are arranged in a staircase pattern in the space in the matrix direction, and the element matrices are mixed with element matrices whose column weights are varied (that each are the number of “1”s in a column direction) and are arranged (see, e.g., Laurent Schmalen, et al, “Next Generation Error Correcting Codes for Lightwave Systems”, ECOC 2014, Cannes-France).

To execute high error correction utilizing the feature of the space coupling LDPC, the column weight of each element matrix needs to be set to be large (the number of values “1” is increased in the column direction). When the column weight is increased, the capability for error correction is improved, however, the processing load of the error correction is increased and the scale of the processing circuit is increased. On the other hand, when the column weight is decreased, the processing amount of the error correction can be decreased and the scale of the processing circuit can be suppressed, however, the capability for the error correction is degraded.

Although Japanese Laid-Open Patent Publication No. 2013-81161 discloses an example where element matrices are mixed with element matrices whose column weights are varied and are arranged, the publication does not disclose any specific arrangement of the element matrices that maximally extracts the effect by the space coupling. The effect of improving the capability for the error correction and of reducing the processing load cannot be simultaneously achieved by a conventional means.

### SUMMARY

According to an aspect of an embodiment, an error correction method of executing error correction for a coded signal using a space coupling LDPC, includes setting a column weight in a column direction of an element matrix that among element matrices of the space coupling LDPC, corresponds to one end side of a bit string of the signal, to be large as a parity check matrix for detecting errors in multiplying the signal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram of a space coupling LDPC represented by a matrix;

FIG. 2 is a diagram of the space coupling LDPC according to an embodiment and represented by matrices;

FIG. 3 is an explanatory diagram of setting a column weight of the space coupling LDPC according to the embodiment;

FIGS. 4 and 5 are protographs each showing the space coupling LDPC;

FIG. 6 is a table of results of a calculation of the column weight of an element matrix of the space coupling LDPC according to the embodiment;

FIG. 7 is a diagram of a column weight distribution of the element matrices in the space coupling LDPC according to the embodiment;

FIGS. 8A and 8B are explanatory graphs of an effect by the space coupling LDPC according to the embodiment;

FIGS. 9 and 10 are diagrams of other examples of distribution settings of the column weights of the element matrix of the space coupling LDPC according to the embodiment;

FIGS. 11A and 11B are diagrams of an example of a system to which the space coupling LDPC according to the embodiment is applied;

FIG. 12 is a diagram of an example of an optical transmission system to which the space coupling LDPC according to the embodiment is applied;

FIG. 13 is a diagram of an OADM unit and a configuration concerning insertion and branching of an optical signal of FIG. 12;

FIG. 14 is a diagram of an internal configuration of a transmitting and receiving device of FIG. 13;

FIG. 15 is a diagram of an internal configuration of a transmitting signal circuit and a receiving signal circuit of FIG. 14;

FIG. 16 is a flowchart of an example of a process by a coding circuit depicted in FIG. 15; and

FIG. 17 is a flowchart of an example of a process by a decoding circuit depicted in FIG. 15.

### DESCRIPTION OF EMBODIMENTS

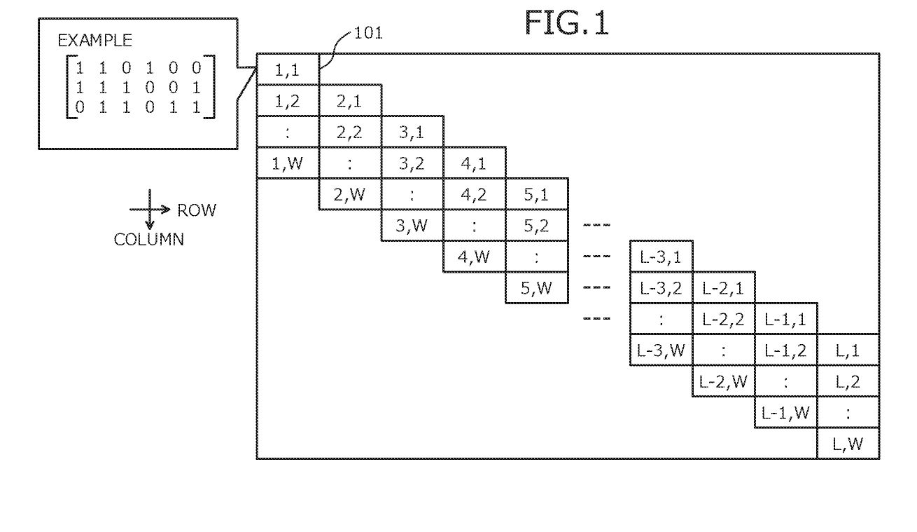

FIG. 1 is a diagram of a space coupling LDPC represented by a matrix. The space coupling LDPC will first be described. FIG. 1 depicts a parity check matrix used in the space coupling LDPC in the form of a mathematical formula matrix. The parity check matrix is used to detect an error and correct the error when a signal receiving apparatus executes a decoding process for a signal. A cell (a small quadrangle) 101 in FIG. 1 is called “element matrix”.

The element matrix 101 has “0”s and “1”s sequentially placed therein to form a matrix having sizes of longitudinal×lateral=(N−K)×N. “K” and “N” are each ordinarily a natural number, where K, N-several hundred to several thousand. “K” and “N” are common to all the element matrices (the cells) 101, and K<N. The “column weight” refers to the number of the value “1” in a column direction in the element matrix 101 (the cell), and the column weights depicted in the example of the simplified matrix of FIG. 1 are “2” for the first column, “3” for the second column, “2” for the third column, “1” for the fourth column, “1” for the fifth column, and “2” for the sixth column.

In an embodiment, ratios of “0” and “1” are defined in the respective element matrix 101. Numbers “1” and “w” in the element matrix (the cell) 101 are defined as follows.

l=1, 2, . . . , L: This represents an index of the element matrix in the lateral direction. The capital L will be referred to as “space coupling length”. The space coupling length represents the number of element matrices in the lateral direction.

w=1, 2, . . . , W: This represents an index of the element matrix in the longitudinal direction. The capital W will be referred to as “space coupling width”. The space coupling width represents the number of element matrices in the longitudinal direction.

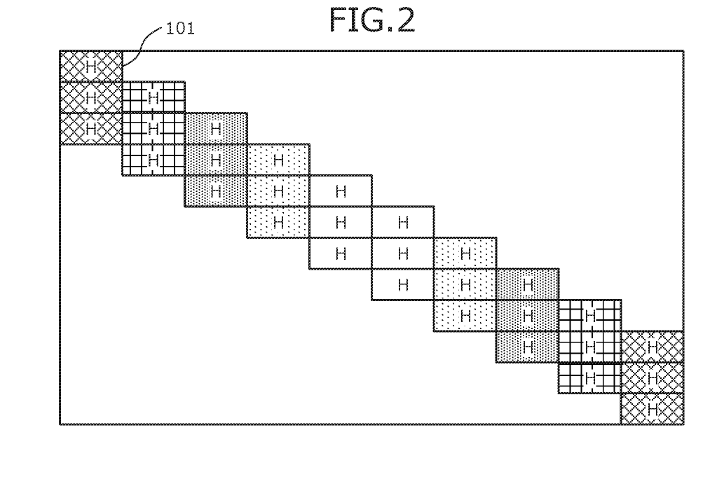

FIG. 2 is a diagram of the space coupling LDPC according to the embodiment and represented by matrices. The space coupling LDPC of the embodiment maximally draws out the effect of the space coupling by setting predetermined variation in the column weight (the number of the value “1” in the column direction in the element matrix) for each of the element matrices (the cells) 101. In FIG. 2, the element matrix (the cell) 101 including the value “1” as the column weight is represented by “H” and the space upper right and the space lower left other than H all have the value “0” (corresponding to L of H/L). In the embodiment, the plural element matrices (the cells) 101 of H including the value “1” are arranged being connected (coupled) to each other in a staircase pattern (in a slope) from upper left down to lower right in the space in the matrix direction.

In the embodiment, as depicted in FIG. 2, the column weights are set to be large toward the ends in the row direction of the overall space coupling LDPC, that is, the sequence of the bits of a received code word (a message), and the column weights are set to be small toward the center thereof. The error correction capability of the signal receiving apparatus can thereby be improved.

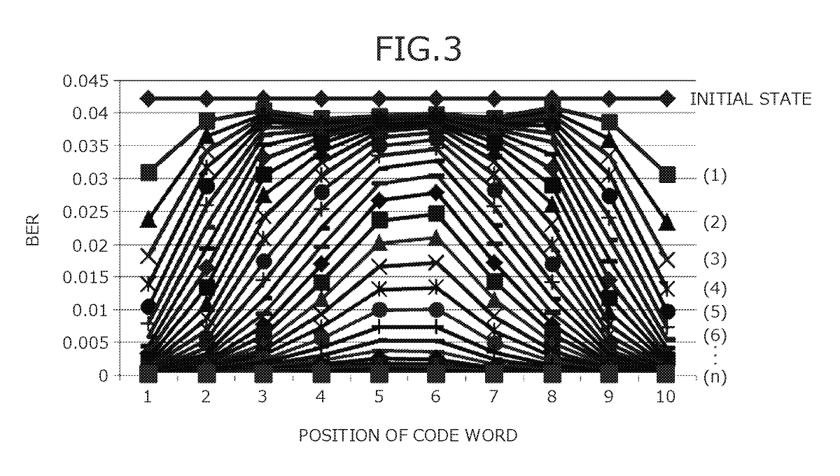

FIG. 3 is an explanatory diagram of setting the column weight of the space coupling LDPC according to the embodiment. The axis of abscissa represents the position (a bit) of the code word and the axis of ordinate represents the bit error rate (BER). In the space coupling LDPC of the embodiment, an error correction capability close to the Shannon limit is obtained by correcting errors from both ends of the code word to be like gradually cutting into the errors.

As depicted in FIG. 3, the code word has a high error in an initial state while the errors at both ends “1, 10” of the bits are first corrected by repeating the correction process. In FIG. 3, (1) to (n) are each the number of error correction sessions and the correction process is repeated until the number of errors becomes zero in all the bits “1 to 10” (for example, several times to about 100 times), and a limit is determined for the number of repetitions of the correction process. In each of the second and subsequent correction processes, errors of the bits toward the center are sequentially corrected based on the bits toward the ends corrected in the previous correction session. The state of the error correction depicted in FIG. 3 will be referred to as “space coupling effect”.

The space coupling effect depicted in FIG. 3 can be achieved by setting the column weights toward the ends to be large and setting the column weights toward the center to be small for the column weight of each of the element matrices (the cells) 101 that are coupled to each other in the staircase pattern in the space coupling LDPC depicted in FIG. 2.

In the embodiment, noting the space coupling effect of correcting errors from the ends of the code word to be like gradually cutting into the errors, the column weights toward the ends are set to be large. The result of the error correction using the element matrices (the cells) 101 at the ends is propagated to adjacent cells (the element matrices) 101 toward the center connected thereto for the error correction to be executed.

In the embodiment, an optimal column weight distribution of the element matrices (the cells) 101 in the space coupling LDPC is obtained by applying a known genetic algorithm thereto (details are described hereinafter).

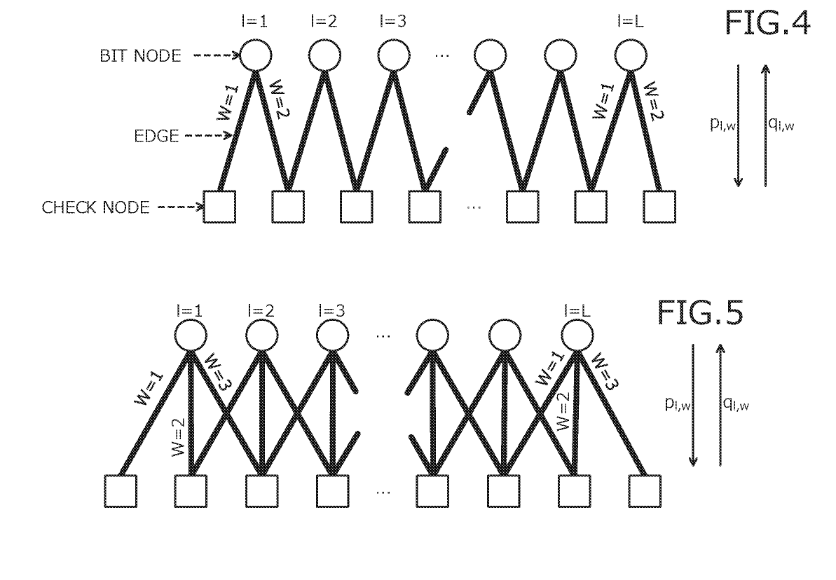

FIGS. 4 and 5 are protographs each showing the space coupling LDPC. The parity check matrix of the space coupling LDPC can also be represented using a protograph. FIG. 4 is the protograph that corresponds to the case depicted in FIG. 1 where W is set to be W=2.
(Bit Node) This abstractly represents a block of N bits (that corresponds to the number of columns of the element matrix).
(Check Node): This represents a set of N-K (corresponding to the number of rows of the element matrix) parity check equations.
Thick Straight Line (Edge): This abstractly represents which parity check equation includes a block of which bit. The number of edges connected to o=the space coupling width W.

FIG. 5 is a protograph that corresponds to the case depicted in FIG. 1 where W is W=3. An approach called “density evolution method” can be explained using a graphic connection by representing the space coupling LDPC in a protograph. A calculation method of the density evolution method in a model of a communication path, generally called “bit erasure communication path” will be described below.

Variables to represent the probability propagation on the edge will be set as follows.

p_{l,w}^{(I)}: This represents the erasure probability of propagation from a block of an l-th bit node to a block of a check node in a w-th direction in an (I)-th decoding session.

q_{l,w}^{(I)}: This represents the erasure probability of propagation from a check node of a w-th direction to a block of an l-th bit node in the (I)-th decoding session.

“ε” is used to represent an initial value of the erasure probability of a bit node. (when I=0.)

p_{l,w}⁽⁰⁾=ε (1)

Incrementing the number of decoding sessions as I=0, 1, 2, . . . , computation sessions of the following two equations are executed alternately and repeatedly. Calculation is executed for combinations of all edges of l and w each time “I” is incremented.

q_{l,w}^{(I)}=1−p_{l,w}(1−p_{l,w}^{(I)})Π_{l′≠l}h_{l,w}(1−p_{l′,w}^{(I)}) (2)

p_{l,w}^{(I)}=ελ_{l,w}(q_{l,w}^{(I-1)})Π_{w′≠w}v_{l,w′}(q_{l,w′}^{(I-1)}) (3)

Simultaneously, an expected value “BER^{(I)}” of the bit erasure probability after the decoding is calculated.

$${BER}^{( l )} = \frac{ɛ}{L} {Σ}_{l} {Π}_{w} {v}_{l , w} ( {q}_{l , w}^{( I )} ) \qquad ( 4 )$$

Before the number of decoding sessions I reaches a limit Iₘₐₓ of the maximal value (generally, 10 to about 1,000), a boundary value “εₜₕ” of ε is obtained by which BER^{(I)} is a desired threshold value BERₜₕ or smaller (that is set to be about 10⁻¹⁵ for optical fiber communication).

ε<εₜₕ [symbol] BER^{(Imax)}<BERₜₕ (5)

The coefficients are obtained of parameters λ_{(l,w)}(x), ρ_{(l,w)}(x), v_{(l,w)}(x), and h_{(l,w)}(x) for εₜₕ to be as large as possible. For example, the coefficients can be obtained using the genetic algorithm with εₜₕ as an evaluation function.

λ_{(l,w)}(x), ρ_{(l,w)}(x), v_{(l,w)}(x), and h_{(l,w)}(x) are respectively a polynomial expression representing a weight distribution in the element matrix that corresponds to the indices of l and w, and are as follows.

Node Distribution of Column Weight (Rate indicating how many “1”s are included in each column of the element matrix.)

v_{l,w}(x)=v_{l,w}_{₁}x+v_{l,w}_{₂}x²+v_{l,w}_{₃}x³+ . . . (Σᵢv_{l,w}_{ᵢ}=1) (6)

Node Distribution of Row Weight (Rate indicating how many “1”s are included in each row of the element matrix.

h_{l,w}(x)=h_{l,w}_{₁}x+h_{l,w}_{₂}x²+v_{l,w}_{₃}x³+ . . . (Σᵢh_{l,w}_{ᵢ}=1) (7)

Edge Distribution of Column Weight (A rate obtained by converting the rate indicating now many “1”s are included in each column of the element matrix into the rate of the edges in the protograph.)

λ_{l,w}(x)=λ_{l,w}_{₁}+λ_{l,w}_{₂}x+λ_{l,w}_{₃}x²+ . . . (Σᵢλ_{l,w}_{ᵢ}=1) (8)

Edge Distribution of Row Weight (A rate obtained by converting the rate indicating how many “1”s are included in each row of the element matrix into the rate of the edges in the protograph.)

ρ_{l,w}(x)=ρ_{l,w}_{₁}+ρ_{l,w}_{₂}x+ρ_{l,w}_{₃}x²+ . . . (Σᵢρ_{l,w}_{ᵢ}=1) (9)

λ_{(l,w)}(x), ρ_{(l,w)}(x), v_{(l,w)}(x), and h_{(l,w)}(x) are not independent parameters and have the following dependency relations thereamong.

$$\begin{matrix}{v}_{l , {w}_{i}} = \frac{{λ}_{l , {w}_{i}} / i}{{Σ}_{j} {λ}_{l , {w}_{j}} / j} & ( 10 ) \\ {h}_{l , {w}_{i}} = \frac{{ρ}_{l , {w}_{i}} / i}{{Σ}_{j} {ρ}_{l , {w}_{j}} / j} & ( 11 )\end{matrix}$$

Equations (2), (3), and (4) are derived applying an existing density evolution method to the models of FIGS. 1, 4, and 5. Equations (1) and, (5) to (11) other than the above are general equations.

In the following description, the space coupling LDPC depicted in FIG. 2, that is, the calculation of the column weight for each of the element matrices (the cells) 101 will be described. In the embodiment, parameters K and N of the sizes of the element matrix (the cell) 101 are fixed and the column weight distribution v_{(l,w)}(x) is obtained from the genetic algorithm. The other functions (λ_{(l,w)}(x), ρ_{(l,w)}(x), and h_{(l,w)}(x)) can be obtained dependently and, in practice, are not especially noted.

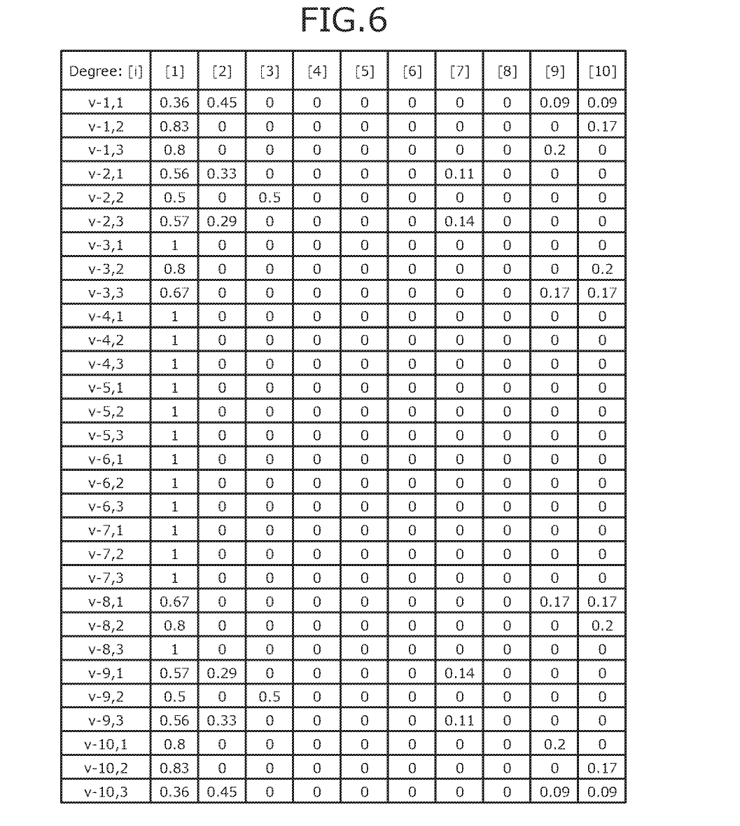

FIG. 6 is a table of results of the calculation of the column weight of the element matrix of the space coupling LDPC according to the embodiment. In FIG. 6, as a condition, K, N, L, and W are set to be K=1,000, N=2,000, L=10, and W=3. As represented by the axis of abscissa in FIG. 6, a limitation is imposed such that the maximal order [i] of the column weight distribution v (l,w) (the largest column weight) is 10 or smaller. The axis of ordinate therein represents the element matrices (the cells) 101. The result of the calculation in FIG. 6 is an example obtained within a predetermined calculation time period, and is not always the numerical value of the optimal order distribution. The conditions such as K, N, L, W, and the maximal order (the maximal value of [i]) are each set corresponding to the operational system.

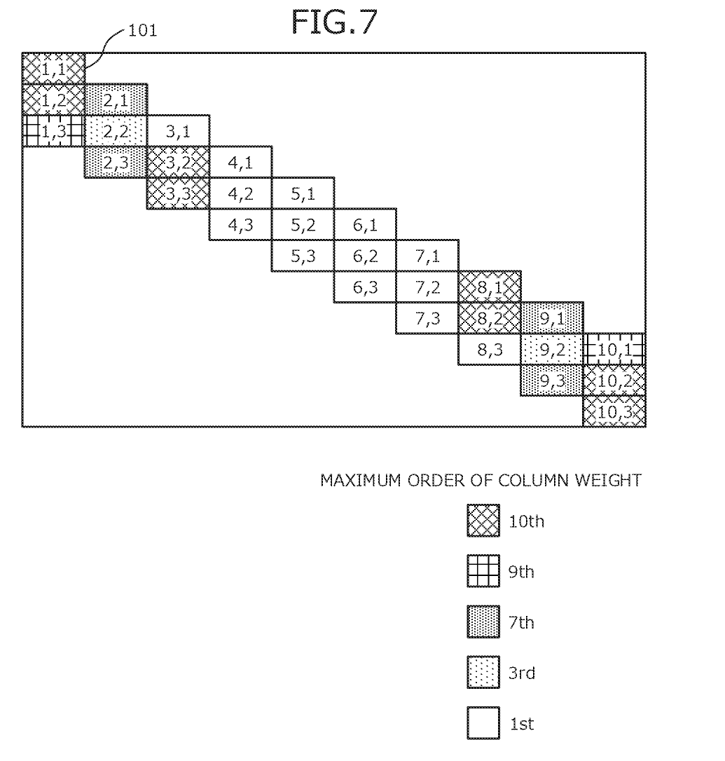

FIG. 7 is a diagram of a column weight distribution of the element matrices in the space coupling LDPC according to the embodiment. FIG. 7 is a diagram of the result of the calculation of FIG. 6 for each height of the maximal order of each of the element matrices (the cells) 101. As depicted in FIG. 7, in the embodiment, for the column weight of each of the element matrices (the cells) 101 in the space coupling LDPC, the element matrices (cells) 101 whose maximal order of the column weight is high are arranged towards the ends while the element matrices (cells) 101 whose maximal order of the column weight is low are arranged toward the center.

As depicted in FIG. 6, when the order distribution in the space coupling LDPC is obtained, a parity check matrix having an excellent nature can be produced using an approach such as a general-purpose Progressive Edge Growth (PEG).

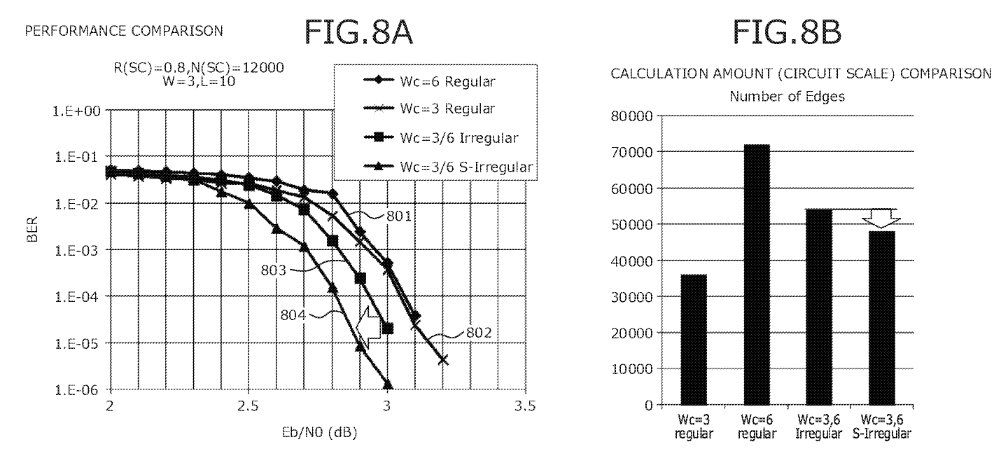

FIGS. 8A and 8B are explanatory graphs of an effect by the space coupling LDPC according to the embodiment. FIG. 8A is a graph showing a relation between the bit error rate, and the signal electric power and the noise electric power. The axis of abscissa thereof represents the ratio of the bit energy to the noise electric power density “Eb/NO (dB)” and the axis of ordinate represents the BER. In the example depicted in FIGS. 8A and 8B, such lines are depicted as a characteristic line 801 obtained when the column weights of the element matrix are each set to be 6 to be even, a characteristic line 802 obtained when the column weights of the element matrix are each set to be 3 to be even, and a characteristic line 803 obtained when the column weights thereof are set to be 3 and 6 to have ratios of 1:1 to be evenly distributed in the space coupling LDPC (that corresponds to the above conventional case by Laurent Schmalen, et al). A characteristic line 804 is also depicted that is obtained when the column weights are set to be 3 and 6 and the distribution thereof is varied such that the maximal order of the column weight becomes higher toward the end in the space coupling LDPC (the embodiment, see FIG. 7).

As depicted in FIG. 8A, the BER and the Eb/NO become more favorable as the column weight becomes larger. According to the embodiment, the BER can be made more favorable than that in a case where the column weights are set to be 3 and 6 to have ratios of 1:1 and are evenly distributed as indicated by the characteristic line 803, by setting the column weights to be 3 and 6 and varying the distribution thereof as indicated by the characteristic line 804.

FIG. 8B is a graph of the calculation amount (the circuit scale) for each of the conditions for setting the column weight depicted in FIG. 8A. The axis of abscissa represents the conditions for setting the column weight depicted in FIG. 8A, and the axis of ordinate represents the calculation amount. As depicted in FIG. 8B, the calculation amount is smallest when the column weight of the element matrix is 3, and the calculation amount becomes progressively larger in cases where: the column weights are set to be 3 and 6, and distribution is varied according to the embodiment; the column weights are set to be 3 and 6 to have the ratios of 1:1 and are evenly distributed; and the column weights are set to be 6.

FIGS. 8A and 8B indicate that the performance can be improved and the calculation amount can be reduced (the circuit scale can be reduced) in the case where the column weights are set to be 3 and 6, and distribution is varied according to the embodiment.

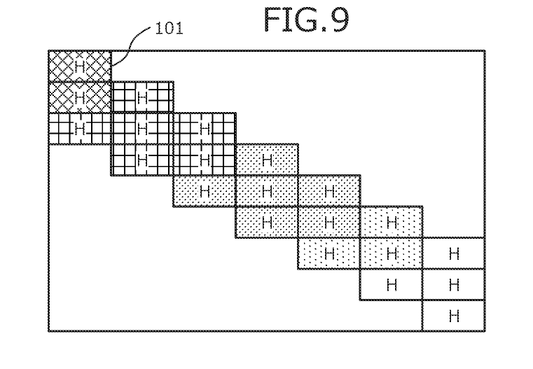

FIGS. 9 and 10 are diagrams of other examples of distribution settings of the column weights of the element matrix of the space coupling LDPC according to the embodiment. In the example depicted in FIG. 9, for the weight of a column of each of the element matrices (the cells) 101 in the space coupling LDPC, the element matrix (the cell) 101 whose order of the column weight is high is arranged toward one end in the row direction (corresponding to the sequence of the bits of the received code word) of the overall space coupling LDPC. The element matrix (the cell) 101 whose order of the column weight is lower is arranged toward the other end. Though the element matrix (the cell) 101 having a higher order of the column weight is arranged toward the starting bit of the code word in FIG. 9, in addition to this, the element matrix (the cell) 101 having a higher order of the column weight may be arranged toward the ending bit of the code word.

Noting the space coupling effect (see FIG. 3), as depicted in FIG. 9, a configuration can be employed that has the element matrix (the cell) 101 whose order of the column weight is high arranged only toward one end in the row direction of the overall space coupling LDPC. According to the setting of the distribution in FIG. 9, the error correction is executed from the side of the one end that has the element matrix (the cell) 101 having the high order of the column weight to be like gradually cutting into the errors. Even with this setting of the distribution, the errors can be corrected in a small number of correction sessions.

FIG. 10 is a diagram of an example of setting of the distribution of the column weights of the element matrices in a space coupling Repeat Accumulate (RA) code that is one of the derivatives of the space coupling LDPC. The space coupling RA code has an advantage that the configuration of a coding circuit (a coding unit) can be simplified. In the space coupling LDPC, the element matrices 101 depicted in FIGS. 7, 9, etc. are set in the receiving apparatus as the parity check matrices. On the other hand, the transmitting apparatus needs to set therein a generator matrix that corresponds to the parity check matrices in the receiving apparatus.

In this regard, for the space coupling RA, code, the distribution of the column weights of the element matrices 101 depicted in FIG. 10 can be used commonly for the transmitting apparatus and the receiving apparatus. For the space coupling RA code, the transmitting apparatus uses the distribution of the column weights of the element matrices 101 depicted in FIG. 10 as the generator matrix and the receiving apparatus uses the distribution of the column weights of the element matrices 101 depicted in FIG. 10 as the parity check matrix. The configuration of the coding circuit can thereby be simplified for the space coupling RA code.

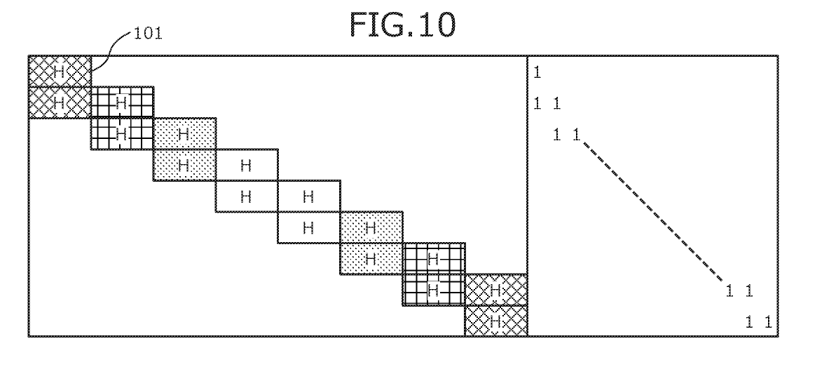

An example of application of an apparatus using the space coupling LDPC of the embodiment will be described. FIGS. 11A and 11B are diagrams of an example of a system to which the space coupling LDPC according to the embodiment is applied. FIG. 11A depicts a communication system. The communication system 1101 includes in a transmitting apparatus, a coding circuit (a coding unit) 1102 that codes a signal to be transmitted, and transmits the signal coded by the coding circuit 1102, to the receiving apparatus through a communication path 1103 such as a radio path or an optical fiber. The receiving apparatus includes a decoding circuit (a decoding unit) 1104 that decodes a transmitted signal and that outputs the decoded signal as a received signal.

FIG. 11B depicts a storage system. The storage system 1111 includes a coding circuit 1112 that codes written-in information, and stores the signal coded by the coding circuit 1112 into a storage medium 1113 such as memory or a disk. The information stored in the storage medium 1113 is decoded by a decoding circuit (a decoding unit) 1114 when the information is read, and is output as readout information.

In the space coupling LDPC of the embodiment, the parity check matrix is used in the error detection and the error correction executed by the decoding circuits 1104 and 1114, and the element matrices (the cells) 101 are used as the parity check matrix.

As depicted in Table 1 below, the coding circuits 1102 and 1112 produce a bit string of a code word c by multiplying a message u that is a signal to be input by a generator matrix G and output the bit string to the communication path 1103 or the storage medium 1113. The decoding circuits 1104 and 1114 detect errors by multiplying a hard decision value of the received word that includes errors by a parity check matrix H as a part of the decoding process to acquire a syndrome s. The generator matrix G and the parity check matrix H are in an orthogonal relation with each other (H×^{t}G=0). When an error-free state is established (no error is present), the syndromes s are all zero and this is an index indicating that the decoding process by each of the decoding circuits 1104 and 1114 is completed.

TABLE 1
CODING
${\underbrace{[ \begin{matrix}{c}_{1} & {c}_{2} & {c}_{3} & {c}_{4} & {c}_{5} & {c}_{6}\end{matrix} ]}}_{c \text{:} CODED WORD} = {\underbrace{[ \begin{matrix}{u}_{1} & {u}_{2} & {u}_{3}\end{matrix} ]}}_{u \text{:} MESSAGE} {\underbrace{[ \begin{matrix}1 & 0 & 0 & 1 & 0 & 1 \\ 0 & 1 & 0 & 1 & 1 & 1 \\ 0 & 0 & 1 & 0 & 1 & 1\end{matrix} ]}}_{G \text{:} GENERATOR MATRIX}$
DECODING
${\underbrace{[ \begin{matrix}1 & 1 & 0 & 1 & 0 & 0 \\ 1 & 1 & 1 & 0 & 0 & 1 \\ 0 & 1 & 1 & 0 & 1 & 0\end{matrix} ]}}_{ \begin{matrix}H \text{:} PARITY \\ CHECK MATRIX\end{matrix}} {\underbrace{[ \begin{matrix}{\hat{c}}_{1} \\ {\hat{c}}_{2} \\ {\hat{c}}_{3} \\ {\hat{c}}_{4} \\ {\hat{c}}_{5} \\ {\hat{c}}_{6}\end{matrix} ]}}_{ \begin{matrix}HARD DECISION VALUE \\ OF RECEIVED WORD\end{matrix}} = {\underbrace{[ \begin{matrix}{s}_{1} \\ {s}_{2} \\ {s}_{3}\end{matrix} ]}}_{s \text{:} SYNDROME}$

Thus, the error correction is thereby executed for a signal when the signal is transmitted through the communication path 1103 or when an error is present in the signal retained by the storage medium 1113, and the signal is output as the received signal or the readout information. The coding circuits 1102 and 1112 have a generator matrix of the space coupling LDPC that corresponds to the parity check matrix of the decoding circuits 1104 and 1114. In the space coupling RA code, the distributions of the column weights are same as that of each other, and the decoding circuit and the coding circuit can use the space coupling LDPC of the same element matrices (the cells) 101.

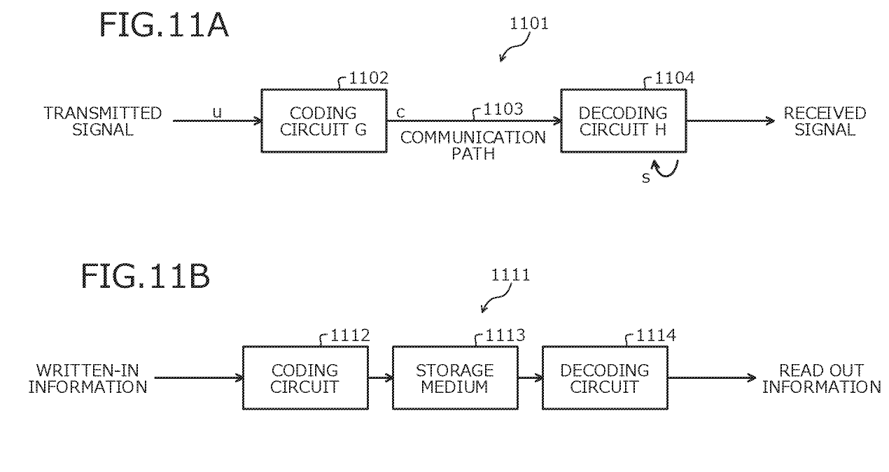

FIG. 12 is a diagram of an example of an optical transmission system to which the space coupling LDPC according to the embodiment is applied. In the optical transmission system 1201, a transmitting apparatus 1204 is arranged at each of plural nodes (OADM nodes) of a pair of communication paths 1202 and 1203 such as a ring network, and plural optical amplifiers (ILA nodes) 1205 are arranged at predetermined distances.

The transmitting apparatus 1204 includes an OADM unit 1211 that inserts (Add) an optical signal at a node into the communication path 1202/or that branches (Drop) an optical signal in the communication paths 1202 and 1203 into a node. The transmitting apparatus 1204 includes a control unit 1216 that controls units that are optical amplifiers (a pre-amplifier and a post-amplifier) 1212, an optical attenuator (an optical ATT) 1213, a supervisory and control light (OSC) detecting unit. 1214, a transmitting and receiving device (TRP) 1215, and a transmitting apparatus 1204. The same configuration as above is also disposed on the side of the communication path 1203.

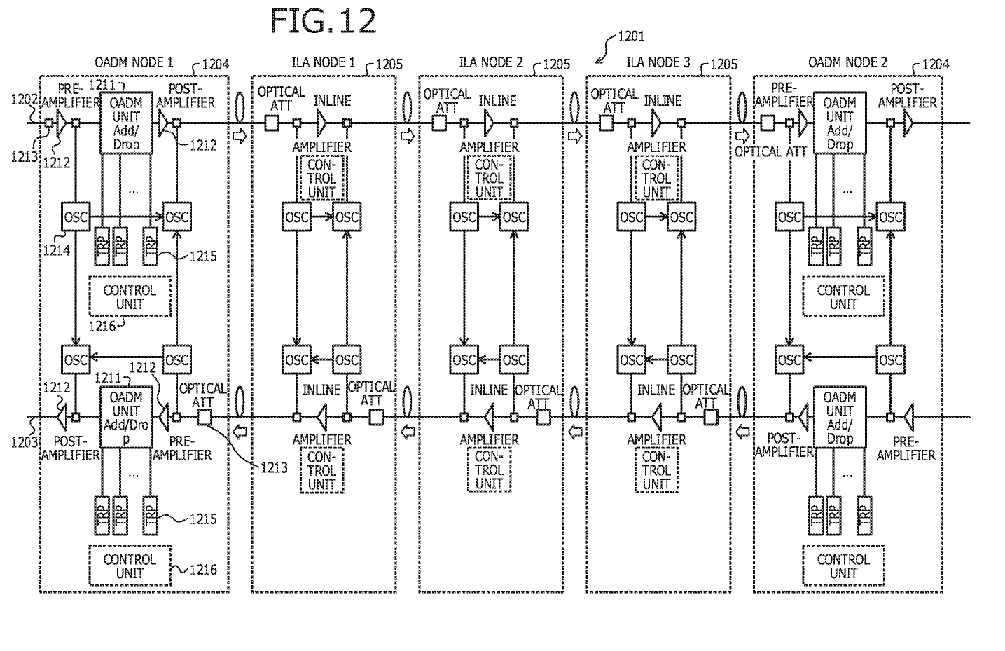

FIG. 13 is a diagram of the OADM unit and a configuration concerning the insertion and the branching of an optical signal of FIG. 12. FIG. 13 depicts the configuration concerning the insertion and the branching of the optical signal to the OADM unit 1211. The OADM unit 1211 includes, for example, 1×n wavelength selection switches (WSS). For an optical signal such as a transmitted WDM, the OADM unit 1211 selects an optical signal having the wavelength for the insertion or the branching, and branches (outputs)/inserts (inputs) to a port of the transmitting and receiving device (TRP) 1215 through the optical amplifier (the optical AMP) 1311 and 1×m optical couplers (CPL) 1312.

In the example of FIG. 13, a WSS 1211a for the branching of the optical signal and a WSS 1211b for the insertion of the optical signal are included and, corresponding to this, the transmitting and receiving device (TRP) 1215 is disposed whose insertion side operates as a transmitting device 1215a and whose branching side operates as a receiving device 1215b. Not limited hereto, the transmitting and receiving device (TRP) 1215 can also be configured to collectively have the transmitting device and the receiving device in one unit.

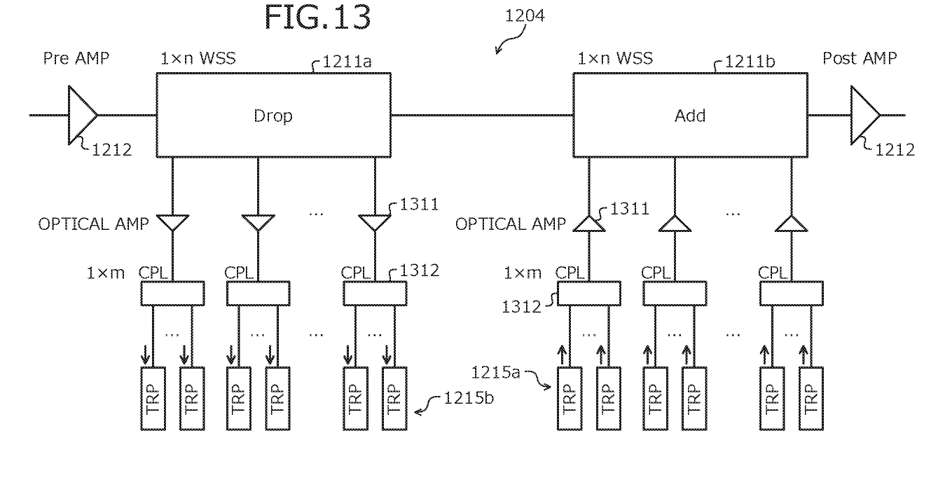

FIG. 14 is a diagram of an internal configuration of the transmitting and receiving device of FIG. 13. The one transmitting and receiving device (TRP) 1400 depicted in FIG. 14 is a transmission and reception module that is formed by collectively including in one unit, the functions of the transmitting device 1215a and the receiving device 1215b depicted in FIG. 13.

The configuration as the transmitting device 1215a includes an Optical-channel Transport Unit (OTU) framer 1401 that executes an input process and an output process for a signal input into a node (Client Signal), a transmitting (Tx) signal circuit 1402 that executes signal processing for a signal to be transmitted, and a DAC 1403 that DA-converts the signal to be transmitted. The configuration also includes a transmitting optical modulator (a transmitting optical Mod.) 1405 that optically modulates the signal to be transmitted using a predetermined scheme and using an output light of an ID 1404 having a predetermined wavelength and that outputs the modulated signal to the optical coupler (CPL) 1312 as an optical signal to be inserted.

The configuration as the receiving device 1215b includes a receiving optical decoder 1412 that optically decodes an optical signal branched and output from the optical coupler (CPL) 1312 using a predetermined scheme and using a light having a predetermined wavelength of an ID 1411, an ADC 1413 that AD-coverts the received signal, a receiving (Rx) signal circuit 1414 that executes signal processing for the received signal, and an OTU framer 1415 that executes an input process and an output process for the received signal and that outputs the received signal to a node as a “Client signal”. The plural OTU framers 1401 and 1415 are included for each of the types of OTU frame and are connected to the Tx signal circuit 1402 and the Rx signal circuit 1414 to execute transmission and reception of the signals.

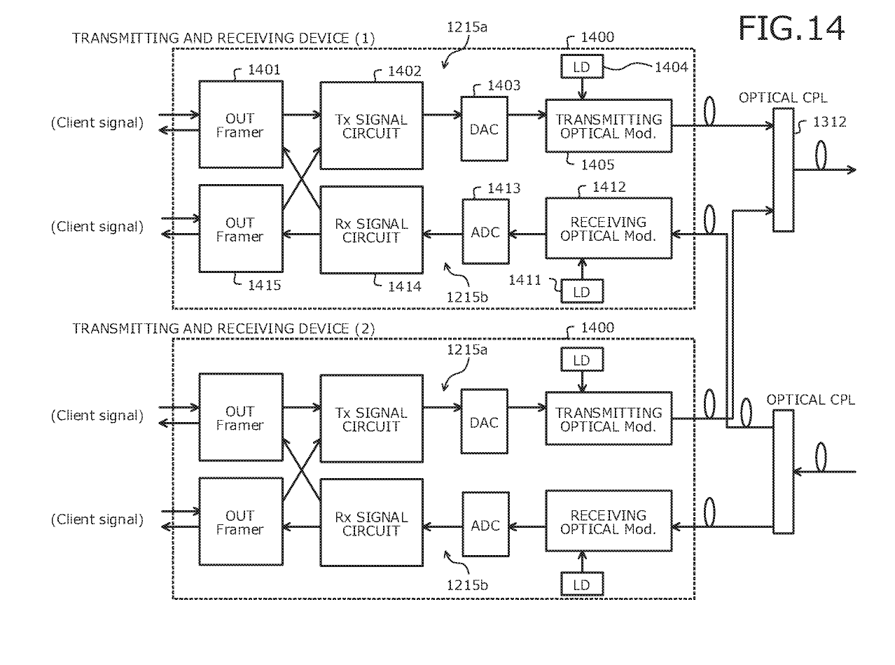

FIG. 15 is a diagram of an internal configuration of the transmitting signal circuit and the receiving signal circuit of FIG. 14. The Tx signal circuit 1402 depicted in FIG. 14 includes an FEC (a coding circuit) 1501 and a pre-equalizing circuit 1502 that are depicted in FIG. 15. The coding circuit 1501 produces based on the generator matrix G, the code word c from the input signal (the message) u output by the node and outputs the code word c to the pre-equalizing circuit 1502. The pre-equalizing circuit 1502 executes wavelength dispersion compensation, frequency offset compensation, input and output property compensation for the DAC 1403 and the transmitting device 1215a, and the like.

The Rx signal circuit 1414 depicted in FIG. 14 includes an equalizing circuit. 1511, a carrier wave phase reconstructing circuit 1512, and an FEC (a decoding circuit) 1513 that are depicted in FIG. 15. The equalizing circuit 1511 executes wavelength dispersion compensation, frequency offset compensation, polarized wave mode dispersion compensation, waveform distortion compensation using a non-linear optical effect, and the like. The carrier wave phase reconstructing circuit 1512 detects a phase difference of the received signal and reconstructs the phase thereof. The FEC (the decoding circuit) 1513 executes the parity check on the received signal the received word) using the parity check matrix H and executes the error correction for the received signal. The received signal after the error correction is output to the node.

The transmitting and receiving device (TRP) 1215 of the transmitting apparatus 1204 at each node is connected to an external apparatus through a connection IF (not depicted). The external apparatus outputs the signal to be transmitted, to the transmitting apparatus 1204 and receives input of the received signal from the transmitting apparatus 1204.

The element matrix (the cell) 101 of the space coupling LDPC described in the embodiment is used as the parity check matrix H of the decoding circuit 1513. A matrix corresponding to the parity check matrix. H is used as the generator matrix G used by the coding circuit 1501. In the space coupling RA code, a common matrix can be used as the generator matrix G of the coding circuit 1501 and the parity check matrix H of the decoding circuit 1513.

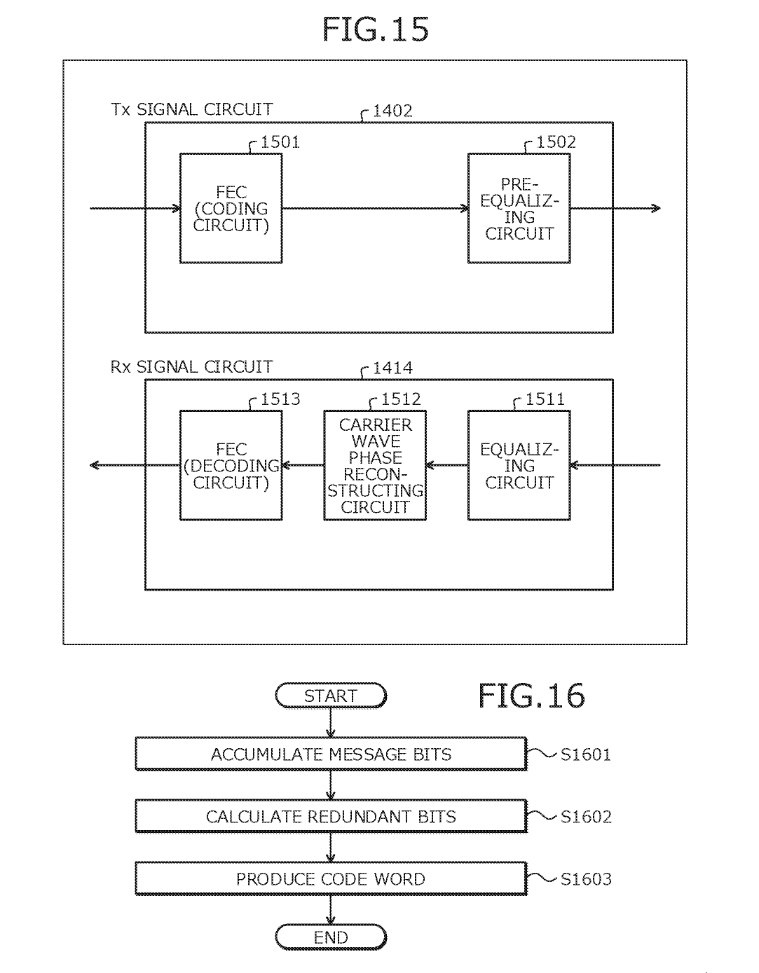

FIG. 16 is a flowchart of an example of a process by the coding circuit depicted in FIG. 15. FIG. 16 depicts the coding process executed by the coding circuit 1501. The coding circuit 1501 accumulates the signals to be transmitted (bits of the message u) output by the node (step S1601) and calculates redundant bits (step S1602). The coding circuit 1501 thereafter codes the message u using the generator matrix G to produce the code word c (step S1603). The code word c produced by the coding circuit 1501 is output from the transmitting and receiving device 1215 to the OADM unit 1211 (inserted into the communication paths 1202 and 1203).

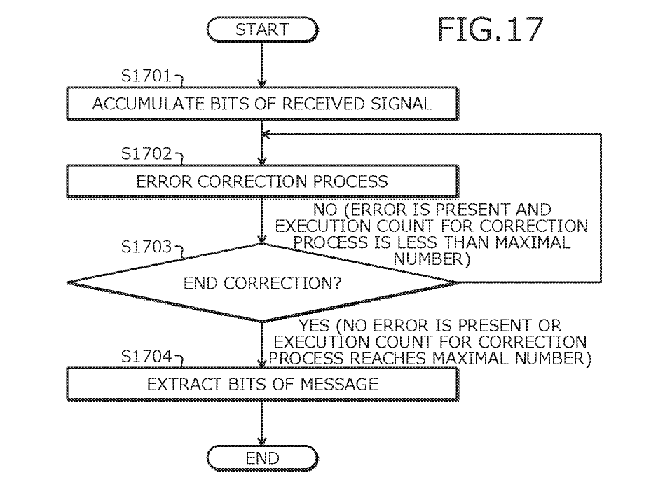

FIG. 17 is a flowchart of an example of a process by the decoding circuit depicted in FIG. 15. FIG. 17 depicts details of a process for correction included in the decoding process executed by the decoding circuit. 1513 disposed in the Rx signal circuit 1414 of the transmitting and receiving device 1215. The decoding circuit 1513 accumulates the bits of the received signal branched from the OADM unit 1211 (the communication paths 1202 and 1203) (step S1701) and executes the error correction process (step S1702). In this error correction process, for the received signal (the received word), the decoding circuit 1513 obtains the syndromes s using the parity check matrix H and repeats the correction process until all the syndromes s becomes zero. The element matrix (the cell) 101 of the space coupling LDPC described in the embodiment is used as the parity check matrix H.

At step S1703, during the time when an error is present and the number of executed correction process sessions is less than the maximal number thereof (step S1703: NO), the decoding circuit 1513 returns to step S1702 to repeat the correction process. When no error is present or when the number of executed correction process sessions reaches the maximal number thereof (step S1703: YES), the decoding circuit 1513 extracts the received signal (the bits of the message) after the errors are corrected (step S1704). The extracted received signal (the message) as output from the transmitting and receiving device 1215 to the node.

According to the embodiment, for the column weight of each element matrix (the cell) in the space coupling LDPC, the column weights are set to be large toward the ends in the row direction (that corresponds to the sequence of the bits of the received code word) of the overall space coupling LDPC and the column weights are set to be small toward the center. The column weight toward at least one of the ends is set to be large. For the repeatedly executed correction process, the errors can thereby be corrected by a small number of correction process sessions (the code rate) and the processing load of the error correction can be reduced due to the space coupling effect of efficiently correcting the errors from the ends of the code word (the bits of the message).

In the embodiment, the column weight of each element matrix is not simply increased or decreased, but rather the element matrices are mixed with the element matrices having varied column weights and the column weights toward the ends are set to be large. The effects of improvement of the capability for the error correction and reduction of the processing load thereof can thereby be simultaneously achieved.

The distribution (the order distribution) of the weights of different columns for each element matrix (the cell) in the space coupling LDPC can be obtained by fixing the parameters K and N of the longitudinal and the lateral sizes of the element matrix (the cell) 101, using the predetermined evaluation function concerning the decoding process, and using the general-purpose genetic algorithm. The acquired order distribution in the space coupling LDPC can be produced as the parity check matrix using the approach such as the general-purpose PEG.

According to one embodiment, effects can be achieved in that the capability for error correction can be improved and processing load can be reduced.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An error correction method of executing error correction for a coded signal using a space coupling LDPC, the error correction method comprising:
setting a column weight in a column direction of an element matrix that among element matrices of the space coupling LDPC, corresponds to one end side of a bit string of the signal, to be large as a parity check matrix for detecting errors in multiplying the signal.

2. The error correction method according to claim 1, wherein
the setting includes setting a column weight in the column direction of element matrices that among the element matrices of the space coupling LDPC, correspond to respective end sides of the bit string of the signal, to be large.

3. The error correction method according to claim 1, wherein
the setting includes setting a column weight in the column direction of an element matrix that among the element matrices of the space coupling LDPC, is on a center side of the bit string of the signal, to be smallest.

4. The error correction method according to claim 1, wherein
the setting includes:
setting a column weight in the column direction of element matrices that among the element matrices of the space coupling LDPC, are of respective end sides of the bit string of the signal, to be large, and
setting a column weight in the column direction of element matrices, to be progressively smaller from the respective end sides toward a center of the bit string of the signal.

5. The error correction method according to claim 1 and further comprising
obtaining a distribution of column weights of the element matrices of the space coupling LDPC, using a genetic algorithm having conditions including longitudinal and lateral sizes of the element matrices, a coupling state of the element matrices, a control value of a number of decoding sessions, and a BER threshold value.

6. A semiconductor device comprising
a decoding circuit that executes error correction for a coded signal using a space coupling LDPC, wherein
the decoding circuit executes the error correction for the signal using a parity check matrix for error detection, the parity check matrix being an element matrix that among element matrices of the space coupling LDPC, corresponds to one end side of a bit string of the signal and that has a column weight in a column direction set to be large.

7. The semiconductor device according to claim 6, wherein
the semiconductor device is used in a decoding device that decodes the signal in a transmitting apparatus of a communication system or a decoding device that reads the signal from a storage medium of a storage system.

8. A transmission and reception module comprising
a decoding circuit that executes error correction for a coded signal using a space coupling LDPC, wherein
the decoding circuit executes the error correction for the signal using a parity check matrix for error detection, the parity check matrix being an element matrix that among element matrices of the space coupling LDPC, corresponds to one end side of a bit string of the signal and has a column weight in a column direction set to be large.

9. A transmitting apparatus comprising
a decoding circuit that executes error correction for a coded signal using a space coupling LDPC, wherein
the decoding circuit executes the error correction for the signal using a parity check matrix for error detection, the parity check matrix being an element matrix that among element matrices of the space coupling LDPC, corresponds to one end side of a bit string of the signal and has a column weight in a column direction set to be large.

10. A transmitting apparatus that executes error correction for a coded signal using a space coupling RA code, the transmitting apparatus comprising
a decoding circuit that decodes the signal and executes error correction for the signal using a parity check matrix for detecting errors, the parity check matrix being an element matrix that among element matrices of a space coupling LDPC, corresponds to one end side of a bit string of the signal and has a column weight in a column direction set to be large; and
a coding circuit that encodes the signal, using a generator matrix for coding, the generator matrix being an element matrix that among element matrices of a space coupling LDPC and similar to the parity check matrix used by the decoding circuit, corresponds to the one end side of the bit string of the signal and has a column weight in a column direction set to be large.
